(19) United States
(12) Patent Application Publication
(10) Pub. No.: US 2026/0164569 A1
(43) Pub. Date: Jun. 11, 2026

(54) Display Mounting Structure and Display Screen Assembly

(71) Applicant: SHENZHEN GLOSHINE TECHNOLOGY CO., LTD., Shenzhen (CN)

(72) Inventors: Xianfeng Zhang, Shenzhen (CN); Guoqiang Li, Shenzhen (CN); Yongfeng Guo, Shenzhen (CN); Xinyong Chen, Shenzhen (CN)

(21) Appl. No.: 19/240,020

(22) Filed: Jun. 17, 2025

Related U.S. Application Data
(63) Continuation of application No. PCT/CN2025/087046, filed on Apr. 3, 2025.

(30) Foreign Application Priority Data
Dec. 6, 2024 (CN) 202423012739.2

(51) Int. Cl. H05K 5/00; H05K 5/02; H10H 29/85

(52) U.S. Cl. CPC H05K 5/0052; H05K 5/0221; H10H 29/8506

(57) ABSTRACT

This application belongs to the technical field of display screens, particularly relating to a display mounting structure and a display screen assembly. The display mounting structure includes a frame, a latching member, and a box body for mounting a display module. The latching member comprises a latching body and a latching hook connected to the latching body; a latching groove, adapted to the latching hook, is provided on a side of the box body; a first groove, adapted to the latching body, is provided on the frame; and the latching body is mounted on the box body by the latching hook engaged in the latching groove, and the frame is mounted on the side of the box body by the latching body inserted into the first groove. The frame is detachably mounted on the box body side via the latching member for easy assembly and disassembly.

### CROSS REFERENCE TO RELATED APPLICATIONS

The present application is a Continuation Application of PCT Application No. PCT/CN 2025/087046 filed on Apr. 3, 2025, which claims priority to Chinese Patent Application No. 202423012739.2, filed on Dec. 6, 2024, entitled “Display Mounting Structure and Display Screen Assembly”, the contents of which are incorporated herein by reference in their entirety.

### TECHNICAL FIELD

The present application relates to the field of display screen technology, and in particular, to a display mounting structure and a display screen assembly.

### BACKGROUND

LED (Light Emitting Diode) display screens are widely used in various fields. Typically, a display screen includes a frame and a display module, where the display module is mounted on the frame and is used to display images. The frame serves to protect the display screen. The present applicant has found that the frame has a fixed shape, and when its side is damaged, the entire frame must be replaced, leading to technical issues such as high replacement costs and prolonged replacement time.

### SUMMARY OF THE DISCLOSURE

To address the technical problem in the prior art where the entire frame must be replaced when the side of the frame is damaged, the present application provides a display mounting structure and a display screen assembly.

In view of the above technical problem, an embodiment of the present application provides a display mounting structure, which includes a frame, a latching member, and a box body for mounting a display module;
wherein the latching member includes a latching body and a latching hook connected to the latching body; a latching groove, adapted to the latching hook, is provided on a side of the box body; a first groove, adapted to the latching body, is provided on the frame; and
the latching body is mounted on the box body by the latching hook engaged in the latching groove, and the frame is mounted on the side of the box body by the latching body inserted into the first groove.

Optionally, the latching member further includes a first elastic arm and a second elastic arm respectively connected to opposite sides of the latching body, and a first protruding hook and a second protruding hook are respectively arranged on opposite inner sidewalls of the first groove; and
when the latching body is inserted into the first groove, the first protruding hook abuts against the first elastic arm, and the second protruding hook abuts against the second elastic arm.

Optionally, the frame includes a side plate and, in sequence and spaced apart, a first vertical plate, a second vertical plate, a third vertical plate, and a fourth vertical plate connected to the side plate; the first groove is arranged between the second vertical plate, the side plate, and the third vertical plate; a second groove is provided between the first vertical plate, the side plate, and the second vertical plate; and a third groove is provided between the third vertical plate, the side plate, and the fourth vertical plate; and
the first protruding hook is arranged at an end of the second vertical plate facing away from the second groove; and the second protruding hook is arranged at an end of the third vertical plate facing away from the third groove.

Optionally, a first inclined surface is provided at an end of the first elastic arm facing away from the latching body; a second inclined surface is provided at an end of the second elastic arm facing away from the latching body; the first protruding hook abuts against the first inclined surface; and the second protruding hook abuts against the second inclined surface.

Optionally, a plurality of pressing blocks are arranged at intervals along the side of the box body; and
each pressing block is engaged in the second groove and/or the third groove.

Optionally, the latching member includes two latching hooks, and the two latching hooks are connected to opposite ends of the latching body along a first direction; two latching grooves are arranged at intervals along the first direction on the side of the box body, and the latching hooks are engaged in the latching grooves in a one-to-one correspondence.

Optionally, the latching member includes two elastic assemblies arranged at intervals along the first direction, and each elastic assembly includes the first elastic arm and the second elastic arm; in the same elastic assembly, the first elastic arm and the second elastic arm are connected to opposite sides of the latching body along a second direction, and the latching hook is located between the first elastic arm and the second elastic arm; the second direction is perpendicular to the first direction.

Optionally, the box body and the frame are both made of aluminum alloy, and the latching member is made of plastic.

Another embodiment of the present application further provides a display screen assembly, which includes a display module and the display mounting structure of any one of claims 1 to 8, wherein the display module is mounted on the box body.

Optionally, a receiving groove is provided on the box body, and the display module is installed in the receiving groove; the display assembly further includes a corner support plate, and opposite sides of the corner support plate are respectively abutted against an inner corner of the receiving groove and an outer corner of the display module.

Optionally, the display screen assembly further includes a battery and a control board installed in the receiving groove, and the control board is electrically connected to the battery and the display module.

Optionally, the battery is provided with a knob, the box body is provided with a locking groove communicating with the receiving groove, and the battery is installed in the receiving groove by the knob locked in the locking groove.

In the present application, the latching body is mounted on the box body by the latching hook engaged in the latching groove, and the frame is mounted on the side of the box body by the latching body inserted into the first groove. In this way, the frame is detachably mounted on the side of the box body via the latching member. The frame can be easily assembled and disassembled from the box body, and serves to protect the box body and the display module, thereby extending the service life of the display mounting structure. If the frame is damaged, it can be independently replaced, thereby reducing the replacement cost and shortening the maintenance period of the display mounting structure. Additionally, the frame can be made in various shapes, colors, and patterns to meet practical requirements, allowing different frames to be selectively mounted on the box body as needed, thereby enhancing the overall aesthetics of the display mounting structure.

### BRIEF DESCRIPTION OF THE DRAWINGS

Further detailed description of the present application is provided below with reference to the accompanying drawings and embodiments.

FIG. 1 is an exploded schematic view of the display mounting structure according to an embodiment of the present application.

FIG. 2 is a sectional view showing the latching member installed on the box body according to an embodiment of the present application.

FIG. 3 is a partial enlarged view of portion A in FIG. 2.

FIG. 4 is a sectional view of the display mounting structure according to an embodiment of the present application.

FIG. 5 is a partial enlarged view of portion B in FIG. 4.

FIG. 6 is a schematic structural view of the frame of the display mounting structure according to an embodiment of the present application.

FIG. 7 is a schematic structural view of the latching member of the display mounting structure according to an embodiment of the present application.

Reference signs in the drawings are as follows
1. Frame; 11. First groove; 12. Side plate; 13. First vertical plate; 14. Second vertical plate; 141. First protruding hook; 15. Third vertical plate; 151. Second protruding hook; 16. Fourth vertical plate; 17. Second groove; 18. Third groove; 2. Latching member; 21. Latching body; 22. Latching hook; 23. First elastic arm; 231. First inclined surface; 24. Second elastic arm; 241. Second inclined surface; 3. Box body; 31. Latching groove; 32. Pressing block; 33. Receiving groove; 4. Display module; 5. Corner support plate; 6. Battery.

### DETAILED DESCRIPTION OF DISCLOSED EMBODIMENTS

To make the technical problems, technical solutions and beneficial effects of the present application more clear, the application will be further explained in detail below with reference to the drawings and embodiments. It should be understood that the specific embodiments described here are only used to illustrate the application, rather than to limit the application.

It should be understood that the terms “upper,” “lower,” “left,” “right,” “front,” “rear,” “middle,” and the like, which indicate orientation or positional relationships, are based on the orientations or positional relationships shown in the drawings. These terms are used merely to facilitate the description of the present application and to simplify the description, and are not intended to indicate or imply that the indicated devices or elements must have a particular orientation, be constructed and operated in a particular orientation, and are therefore not to be construed as limiting the present application.

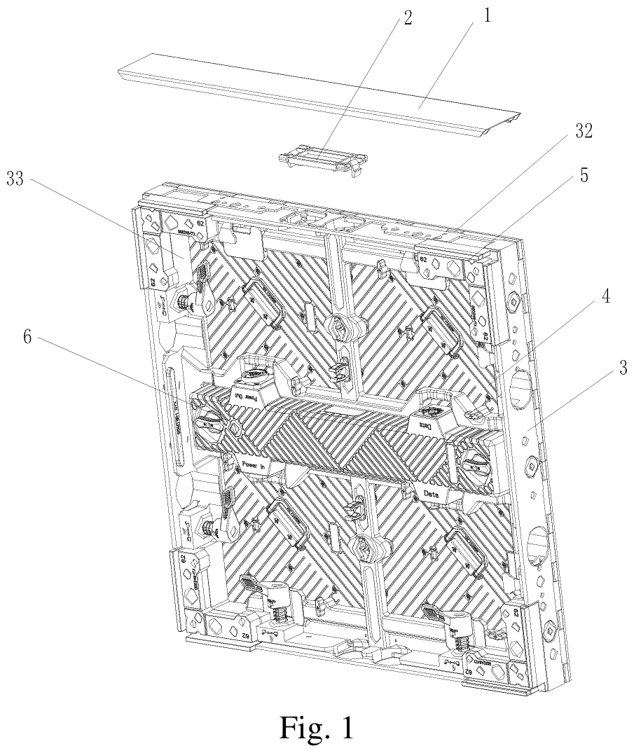

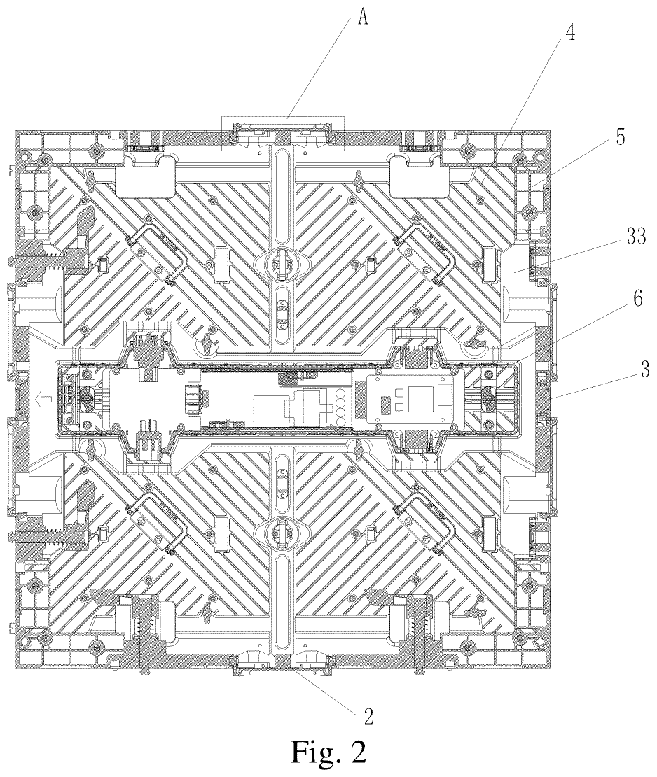

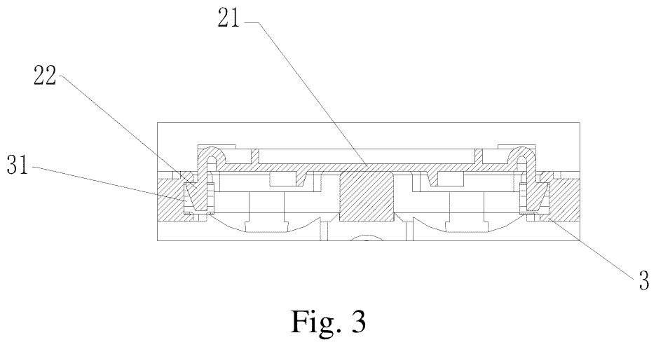

As shown in FIGS. 1 to 5, an embodiment of the present application provides a display mounting structure, which includes a frame 1, a latching member 2, and a box body 3 for mounting a display module 4; the latching member 2 includes a latching body 21 and a latching hook 22 connected to the latching body 21. The side of the box body 3 is provided with a latching groove 31 adapted to the latching hook 22, and the frame 1 is provided with a first groove 11 adapted to the latching body 21. It is understood that the latching body 21 and the latching hook 22 are integrally formed. The display module 4 includes, but is not limited to, an LED screen. In a specific embodiment, both the box body 3 and the frame 1 are made of aluminum alloy, and the latching member 2 is made of plastic.

The latching body 21 is mounted on the box body 3 by engaging the latching hook 22 into the latching groove 31 of the box body 3. The frame 1 is mounted on the side of the box body 3 by inserting the latching body 21 into the first groove 11 of the frame 1. It is understood that latching members 2 are installed on all four sides of the box body 3, and the four frames 1 are respectively mounted on the four sides of the box body 3 via the latching members 2.

In the present application, the latching body 21 is mounted on the box body 3 by the latching hook 22 engaged in the latching groove 31, and the frame 1 is mounted on the side of the box body 3 by the latching body 21 inserted into the first groove 11. In this way, the frame 1 is detachably mounted on the side of the box body 3 via the latching member 2. The frame 1 can be easily assembled and disassembled from the box body 3 and serves to protect both the box body 3 and the display module 4, thereby extending the service life of the display mounting structure. If the frame 1 is damaged, it can be independently replaced, which reduces the replacement cost and shortens the maintenance period of the display mounting structure. Additionally, the frame 1 can be provided in various shapes, colors, and patterns according to practical needs, allowing different frames 1 to be selectively mounted on the box body 3 as needed, thereby enhancing the overall aesthetics of the display mounting structure.

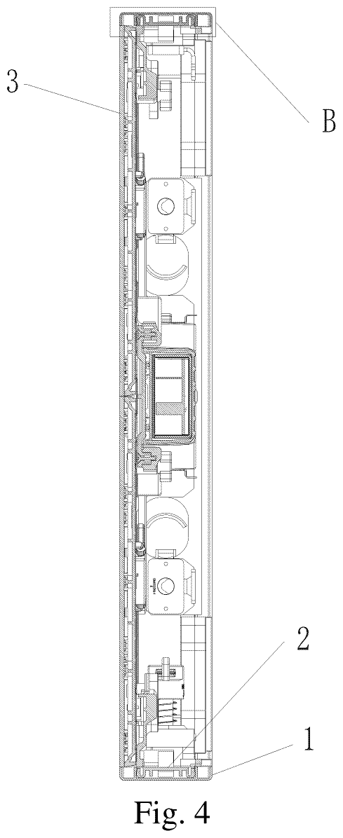

In one embodiment, as shown in FIGS. 4 to 7, the latching member 2 further includes a first elastic arm 23 and a second elastic arm 24 connected to opposite sides of the latching body 21. The opposite inner sidewalls of the first groove 11 are respectively provided with a first protruding hook 141 and a second protruding hook 151. It is understood that the first elastic arm 23, the second elastic arm 24, the latching body 21, and the latching hook 22 are integrally formed. The first protruding hook 141 and the second protruding hook 151 both protrude toward the center of the first groove 11.

When the latching body 21 is inserted into the first groove 11, the first protruding hook 141 abuts against the first elastic arm 23, and the second protruding hook 151 abuts against the second elastic arm 24.

Specifically, during the insertion of the latching body 21 into the first groove 11, the opposite side walls of the first groove 11 respectively press against the first elastic arm 23 and the second elastic arm 24. Meanwhile, the first protruding hook 141 presses tightly against the first elastic arm 23, and the second protruding hook 151 presses tightly against the second elastic arm 24. As a result, the first elastic arm 23 and the second elastic arm 24 are interference-fitted into the first groove 11, ensuring the stability of the frame 1 mounted on the latching member 2.

In one embodiment, as shown in FIGS. 4 to 6, the frame 1 includes a side plate 12 and first vertical plate 13, second vertical plate 14, third vertical plate 15, and fourth vertical plate 16 sequentially and spacedly connected to the side plate 12. The first groove 11 is provided between the second vertical plate 14, the side plate 12, and the third vertical plate 15. A second groove 17 is provided between the first vertical plate 13, the side plate 12, and the second vertical plate 14, and a third groove 18 is provided between the third vertical plate 15, the side plate 12, and the fourth vertical plate 16. It can be understood that the first vertical plate 13, the second vertical plate 14, the third vertical plate 15, the fourth vertical plate 16, and the side plate 12 are integrally formed. The second groove 17 and the third groove 18 are respectively located on opposite sides of the first groove 11. The first vertical plate 13 and the fourth vertical plate 16 are respectively connected to opposite sides of the side plate 12, and the second vertical plate 14 and the third vertical plate 15 are positioned between the first vertical plate 13 and the fourth vertical plate 16.

The first protruding hook 141 is arranged at the end of the second vertical plate 14 facing away from the second groove 17, and the second protruding hook 151 is arranged at the end of the third vertical plate 15 facing away from the third groove 18.

In this embodiment, the design of the second groove 17 allows the second vertical plate 14 to have a certain elasticity, enabling the second vertical plate 14 to press against the first elastic arm 23; similarly, the design of the third groove 18 allows the third vertical plate 15 to have a certain elasticity, enabling the third vertical plate 15 to press against the second elastic arm 24. The designs of the second groove 17 and the third groove 18 further ensure the stability of the frame 1 when mounted on the latching member 2.

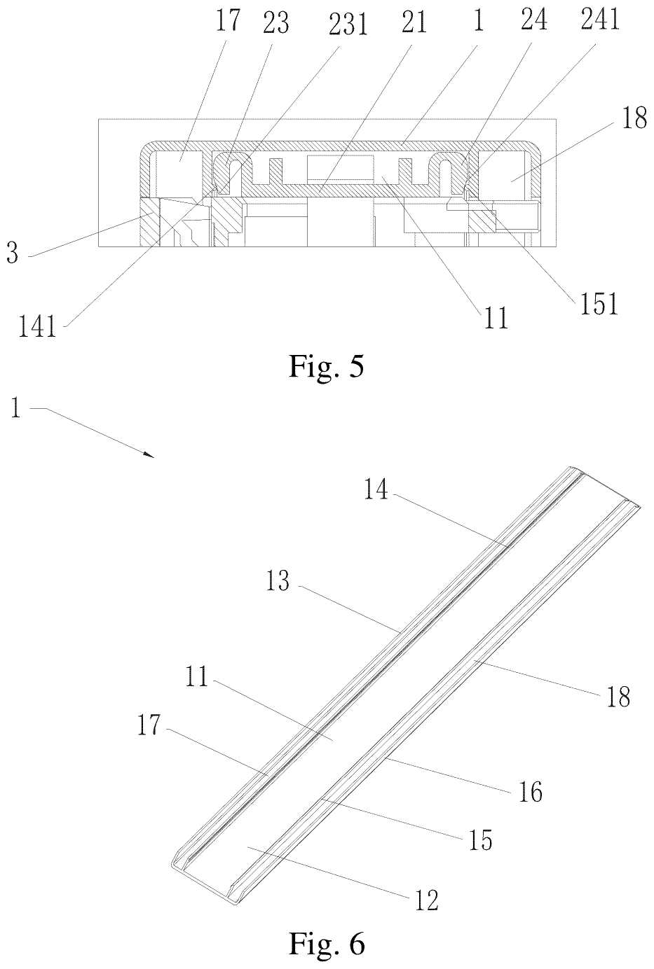

In one embodiment, as shown in FIGS. 4 and 5, the first elastic arm 23 has a first inclined surface 231 at the end facing away from the latching body 21, and the second elastic arm 24 has a second inclined surface 241 at the end facing away from the latching body 21. The first protruding hook 141 abuts against the first inclined surface 231, and the second protruding hook 151 abuts against the second inclined surface 241.

Specifically, during the insertion of the latching body 21 into the first groove 11, the first protruding hook 141 presses against the first elastic arm 23 through the first inclined surface 231, and the second protruding hook 151 presses against the second elastic arm 24 through the second inclined surface 241. In this way, the first protruding hook 141 tightly presses the first elastic arm 23 via the first inclined surface 231, and the second protruding hook 151 tightly presses the second elastic arm 24 via the second inclined surface 241, thereby further ensuring the stability of the frame 1 mounted on the latching member 2.

In one embodiment, as shown in FIG. 1, the side of the box body 3 is further provided with a plurality of pressing blocks 32 distributed at intervals. The pressing blocks 32 are engaged in the second groove 17 and/or the third groove 18. It is understood that the number of pressing blocks 32 can be set according to actual needs. The pressing blocks 32 can press the second vertical plate 14 and/or the third vertical plate 15 toward the first groove 11, so that the second vertical plate 14 and the third vertical plate 15 can press the latching body 21 from both left and right sides.

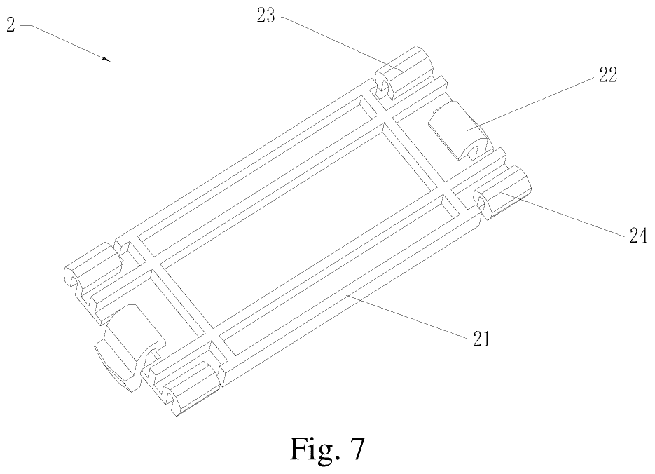

In one embodiment, as shown in FIG. 7, the latching member 2 includes two latching hooks 22, and two latching grooves 31 are connected at opposite ends of the latching body 21 along a first direction; the side of the box body 3 is provided with two latching grooves 31 distributed at intervals along the first direction, and the latching hooks 22 are correspondingly engaged in the latching grooves 31 one-to-one. It is understood that the first direction may be the lengthwise or widthwise direction of the box body 3. In this embodiment, the latching member 2 is installed on the side of the box body 3 by engaging the two latching hooks 22 in the two latching grooves 31, thereby ensuring the stability of the latching member 2 mounted on the box body 3.

In one embodiment, as shown in FIG. 7, the latching member 2 includes two elastic assemblies distributed at intervals along the first direction. Each elastic assembly includes the first elastic arm 23 and the second elastic arm 24. Within the same elastic assembly, the first elastic arm 23 and the second elastic arm 24 are connected to opposite sides of the latching body 21 along a second direction, and the latching hook 22 is located between the first elastic arm 23 and the second elastic arm 24. The second direction is perpendicular to the first direction. It is understood that the second direction corresponds to the height direction of the box body 3. Within the same elastic assembly, the first elastic arm 23 and the second elastic arm 24 are symmetrically arranged on opposite sides of the latching hook 22.

In this embodiment, the design of the two elastic assemblies further ensures the stability of the frame 1 mounted on the latching member 2.

As shown in FIG. 1, another embodiment of the present application provides a display screen assembly, which includes the display module 4 and the above-mentioned display mounting structure. The display module 4 is mounted on the box body 3. It is to be understood that the display module 4 includes but is not limited to an LED screen, and the display module 4 can be composed of multiple display screens. In the present application, the display module 4 is mounted on the box body 3, and the frame 1 is mounted on the side of the box body 3 via the latching member 2, so that the frame 1 can protect the display module 4 inside the box body 3, thereby extending the service life of the display screen assembly.

In one embodiment, as shown in FIG. 1, the box body 3 is provided with a receiving groove 33, and the display module 4 is installed in the receiving groove 33; the display assembly further includes corner support plates 5, with the opposite sides of each corner support plate 5 respectively abutting against the inner corner of the receiving groove 33 and the outer corner of the display module 4. It is to be understood that four corner support plates 5 are provided, each installed at one of the four corners of the receiving groove 33. The display module 4 can be installed in the receiving groove 33 via screws, snap fasteners, or other connectors. The corner support plates 5 abut the corners of the display module 4, thereby serving to protect the corners of the display module 4.

In one embodiment, as shown in FIG. 1, the display assembly further includes a battery 6 and a control board installed in the receiving groove 33, and the control board is electrically connected to both the battery 6 and the display module 4. It is understood that the battery 6 can supply power to the display module 4 and other components, and the design of the battery 6 and the control board improves the integration level of the display assembly.

In one embodiment, a knob is provided on the battery 6, and the box body 3 is provided with a locking groove communicating with the receiving groove 33; the battery 6 is installed in the receiving groove 33 by locking the knob into the locking groove. It can be understood that by rotating the knob, the rotating hook on the knob can engage in the locking groove for locking or disengage from it. When the rotating hook on the knob is engaged in the locking groove, the battery 6 is fixedly installed in the receiving groove 33; when the rotating hook on the knob disengages from the locking groove, the battery 6 can be removed from the receiving groove 33. In this embodiment, the assembly and disassembly operation between the battery 6 and the box body 3 is simple.

The above are merely the preferred embodiments of the display mounting structure and display screen assembly of this application, and are not intended to limit the scope of the application. Any modification, equivalent substitution and improvement made within the spirit and principle of this application shall be included in the protection scope of this application.

What is claimed is:

1. A display mounting structure, comprising:
a frame, a latching member, and a box body for mounting a display module;
wherein the latching member comprises a latching body and a latching hook connected to the latching body; a latching groove, adapted to the latching hook, is provided on a side of the box body; a first groove, adapted to the latching body, is provided on the frame; and
the latching body is mounted on the box body by the latching hook engaged in the latching groove, and the frame is mounted on the side of the box body by the latching body inserted into the first groove.

2. The display mounting structure of claim 1, wherein:
the latching member further comprises a first elastic arm and a second elastic arm respectively connected to opposite sides of the latching body, and a first protruding hook and a second protruding hook are respectively arranged on opposite inner sidewalls of the first groove; and
when the latching body is inserted into the first groove, the first protruding hook abuts against the first elastic arm, and the second protruding hook abuts against the second elastic arm.

3. The display mounting structure of claim 2, wherein:
the frame comprises a side plate and, in sequence and spaced apart, a first vertical plate, a second vertical plate, a third vertical plate, and a fourth vertical plate connected to the side plate; the first groove is arranged between the second vertical plate, the side plate, and the third vertical plate; a second groove is provided between the first vertical plate, the side plate, and the second vertical plate; and a third groove is provided between the third vertical plate, the side plate, and the fourth vertical plate; and
the first protruding hook is arranged at an end of the second vertical plate facing away from the second groove; and the second protruding hook is arranged at an end of the third vertical plate facing away from the third groove.

4. The display mounting structure of claim 3, wherein:
a first inclined surface is provided at an end of the first elastic arm facing away from the latching body; a second inclined surface is provided at an end of the second elastic arm facing away from the latching body; the first protruding hook abuts against the first inclined surface;
and the second protruding hook abuts against the second inclined surface.

5. The display mounting structure of claim 3, wherein:
a plurality of pressing blocks are arranged at intervals along the side of the box body; and
each pressing block is engaged in the second groove and/or the third groove.

6. The display mounting structure of claim 2, wherein:
the latching member comprises two latching hooks, and the two latching hooks are connected to opposite ends of the latching body along a first direction; two latching grooves are arranged at intervals along the first direction on the side of the box body, and the latching hooks are engaged in the latching grooves in a one-to-one correspondence.

7. The display mounting structure of claim 6, wherein:
the latching member comprises two elastic assemblies arranged at intervals along the first direction, and each elastic assembly comprises the first elastic arm and the second elastic arm; in the same elastic assembly, the first elastic arm and the second elastic arm are connected to opposite sides of the latching body along a second direction, and the latching hook is located between the first elastic arm and the second elastic arm; the second direction is perpendicular to the first direction.

8. The display mounting structure of claim 1, wherein:
the box body and the frame are both made of aluminum alloy, and the latching member is made of plastic.

9. A display screen assembly, comprising:
a display module and the display mounting structure of claim 1, wherein the display module is mounted on the box body.

10. The display screen assembly of claim 9, wherein:
a receiving groove is provided on the box body, and the display module is installed in the receiving groove; the display assembly further comprises a corner support plate, and opposite sides of the corner support plate are respectively abutted against an inner corner of the receiving groove and an outer corner of the display module.

11. The display screen assembly of claim 10, wherein:
the display screen assembly further comprises a battery and a control board installed in the receiving groove, and the control board is electrically connected to the battery and the display module.

12. The display screen assembly of claim 11, wherein:
the battery is provided with a knob, the box body is provided with a locking groove communicating with the receiving groove, and the battery is installed in the receiving groove by the knob locked in the locking groove.

13. A display screen assembly, comprising:
a display module and the display mounting structure of claim 2, wherein the display module is mounted on the box body.

14. A display screen assembly, comprising:
a display module and the display mounting structure of claim 3, wherein the display module is mounted on the box body.

15. A display screen assembly, comprising:
a display module and the display mounting structure of claim 4, wherein the display module is mounted on the box body.

16. A display screen assembly, comprising:
a display module and the display mounting structure of claim 5, wherein the display module is mounted on the box body.

17. A display screen assembly, comprising:
a display module and the display mounting structure of claim 6, wherein the display module is mounted on the box body.

18. A display screen assembly, comprising:
a display module and the display mounting structure of claim 7, wherein the display module is mounted on the box body.

19. A display screen assembly, comprising:
a display module and the display mounting structure of claim 8, wherein the display module is mounted on the box body.
